(19) United States
(12) Patent Application Publication
(10) Pub. No.: US 2012/0052623 A1
(43) Pub. Date: Mar. 1, 2012

(54) METHOD TO ADHERE A LAMINA TO A RECEIVER ELEMENT USING GLASS FRIT PASTE

(75) Inventors: Mohamed M. Hilali, Sunnyvale, CA (US); Venkateswaran Subbaraman, San Jose, CA (US); John Alexander, San Jose, CA (US)

(73) Assignee: Twin Creeks Technologies, Inc., San Jose, CA (US)

(21) Appl. No.: 12/872,629

(22) Filed: Aug. 31, 2010

(51) Int. Cl. H01L 31/18

(52) U.S. Cl. 438/98; 438/57; 257/E31.124

(57) ABSTRACT

A method is provided to adhere a lamina to a receiver element using a glass frit mixture. A donor body having a previously defined cleave plane and a receiver element are provided. The glass frit mixture is applied to either the donor body or the receiver element, or both, and is first dried to drive off solvents, then heated to burn out organics. If the glass frit mixture is applied to the receiver, the receiver element and glass frit mixture may be heated to the flow temperature of the frit. Following burn out of organics, the glass frit mixture will undergo no additional outgassing or densification. The receiver element and the donor body are then juxtaposed, the glass frit layer between them. The structure is heated further to permanently adhere the surfaces and to cleave a lamina from the donor body at the cleave plane. A device such as a photovoltaic cell is fabricated, the cell comprising the lamina.

### BACKGROUND OF THE INVENTION

A conventional prior art photovoltaic cell includes a p-n diode; an example is shown in FIG. 1. A depletion zone forms at the p-n junction, creating an electric field. Incident photons (incident light is indicated by arrows) will knock electrons from the valence band to the conduction band, creating free electron-hole pairs. Within the electric field at the p-n junction, electrons tend to migrate toward the n region of the diode, while holes migrate toward the p region, resulting in current, called photocurrent. Typically the dopant concentration of one region will be higher than that of the other, so the junction is either a p+/n− junction (as shown in FIG. 1) or a n+/p− junction. The more lightly doped region is known as the base of the photovoltaic cell, while the more heavily doped region, of opposite conductivity type, is known as the emitter. Most carriers are generated within the base, and it is typically the thickest portion of the cell. The base and emitter together form the active region of the cell. The cell also frequently includes a heavily doped contact region in electrical contact with the base, and of the same conductivity type, to improve current flow. In the example shown in FIG. 1, the heavily doped contact region is n-type.

The invention relates to a method to form a structure including a thin lamina adhered to a receiver element using glass frit paste. The structure is suitable for fabrication of devices, including photovoltaic devices.

Most conventional adhesives will densify and release volatiles if heated; thus structures bonded with adhesives often cannot tolerate heating.

### SUMMARY OF THE INVENTION

The present invention is defined by the following claims, and nothing in this section should be taken as a limitation on those claims. In general, the invention is directed to a method to adhere a thin lamina to a receiver element using glass frit paste.

A first aspect of the invention provides for a method to fabricate a structure, the method comprising: providing a semiconductor donor body, wherein a cleave plane has been defined within the donor body; providing a receiver element; applying a mixture containing glass frit to a first surface of the donor body or to a first surface of the receiver element; heating the applied glass frit mixture to at least 325 degrees C.; after the step of heating the applied glass frit mixture, placing the first surface of the donor body and the first surface of the receiver element in contact, the heated glass frit mixture disposed between them; and heating the donor body and the receiver element, wherein, during this heating step, a lamina cleaves from the donor body at the cleave plane, the lamina remaining permanently adhered to the receiver element.

Another aspect of the invention provides for a method to fabricate a structure, the method comprising: providing a semiconductor donor body, wherein a cleave plane has been defined within the donor body; providing a receiver element; applying a mixture containing glass frit to a first surface of the donor body or to a first surface of the receiver element; heating the applied glass frit mixture to at least 325 degrees C.; after the step of heating the applied glass frit mixture, placing the first surface of the donor body and the first surface of the receiver element in contact, the heated glass frit mixture disposed between them; and heating the donor body and the receiver element, wherein, during this heating step, a lamina cleaves from the donor body at the cleave plane, the lamina remaining permanently adhered to the receiver element, wherein the lamina is suitable for use in a photovoltaic cell.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a cross-sectional view of a prior art photovoltaic cell.

FIGS. 2a-2d are cross-sectional views of stages of fabrication of a photovoltaic cell formed according to an embodiment of U.S. patent application Ser. No. 12/026530.

FIGS. 3a-3c are cross-sectional views illustrating stages in formation of a structure according to aspects of the present invention.

FIGS. 4a-4c are cross-sectional views illustrating stages in formation of a structure according to aspects of the present invention.

FIG. 5 is a flow chart detailing the steps of a method according to aspects of the present invention.

FIGS. 6a-6f are cross-sectional views illustrating stages in formation of a structure according to an embodiment of the present invention.

FIGS. 7a and 7b are cross-sectional views illustrating stages in formation of a structure according to another embodiment of the present invention.

FIGS. 8a and 8b are views of a receiver element that may be used with the present invention. FIG. 8a is a plan view, and FIG. 8b is a cross-sectional view.

FIG. 9 is a cross-sectional view of another embodiment according to the present invention which allows ready electrical access to the bonded face of a photovoltaic cell.

FIG. 10 is a cross-sectional view of another embodiment according to the present invention which may enhance electrical contact to the photovoltaic cell.

### DETAILED DESCRIPTION OF THE EMBODIMENTS

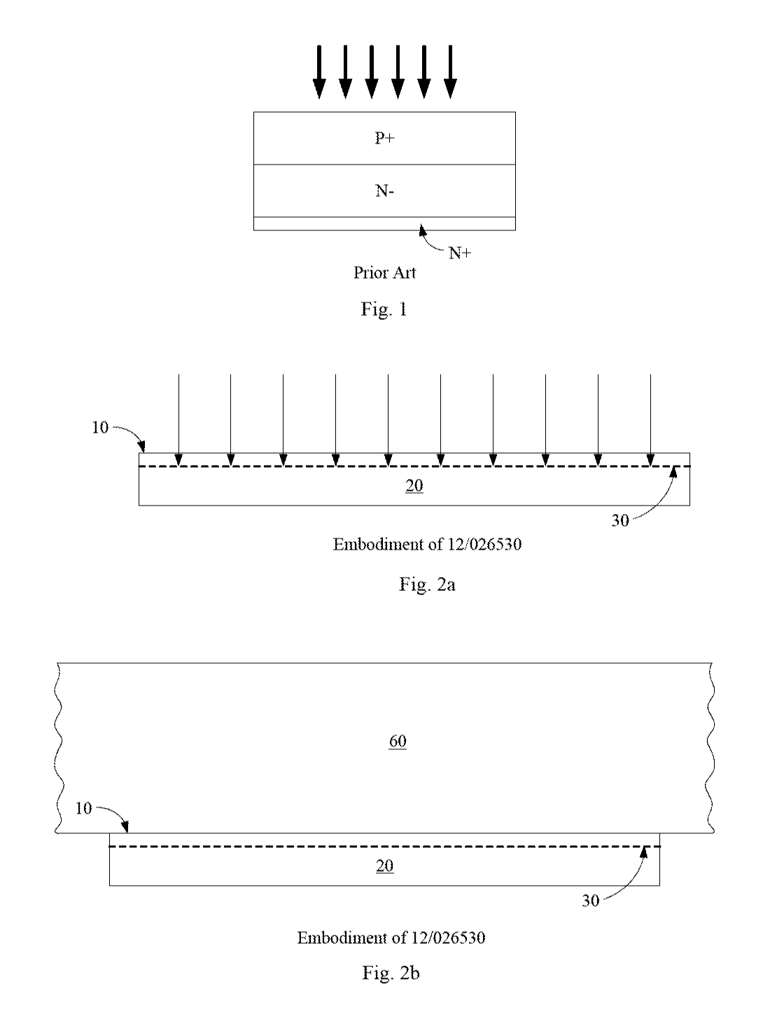

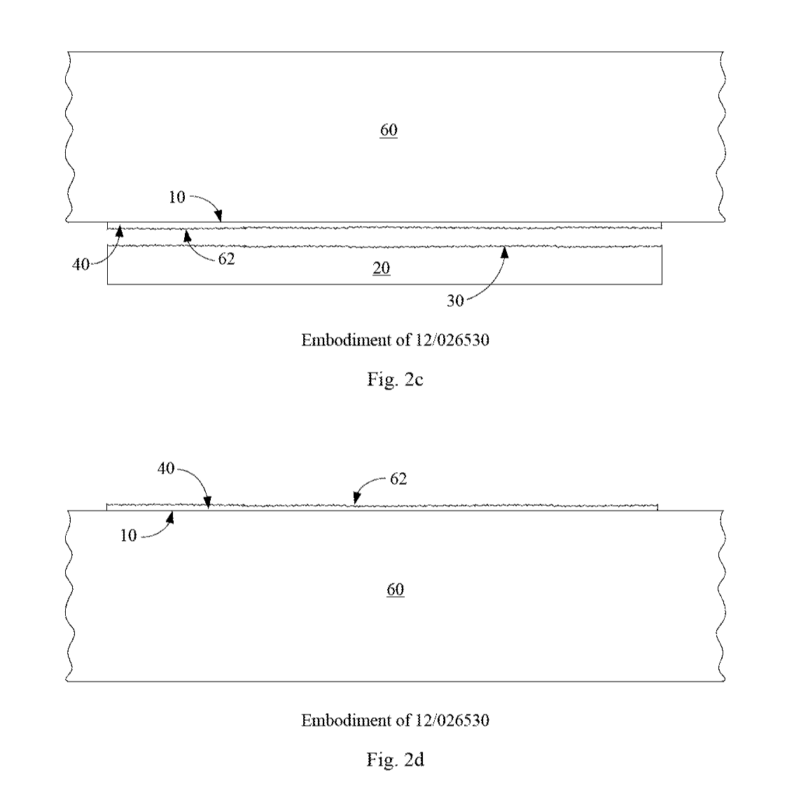

Sivaram et al., U.S. patent application Ser. No. 12/026530, “Method to Form a Photovoltaic Cell Comprising a Thin Lamina,” filed Feb. 5, 2008, owned by the assignee of the present invention and hereby incorporated by reference, describes fabrication of a photovoltaic cell comprising a thin semiconductor lamina formed of non-deposited semiconductor material. Referring to FIG. 2a, in embodiments of Sivaram et al., a semiconductor donor wafer 20 is implanted through first surface 10 with one or more species of gas ions, for example hydrogen and/or helium ions. The implanted ions define a cleave plane 30 within the semiconductor donor wafer. As shown in FIG. 2b, donor wafer 20 is affixed at first surface 10 to receiver 60. Referring to FIG. 2c, an anneal causes lamina 40 to cleave from donor wafer 20 at cleave plane 30, creating second surface 62. In embodiments of Sivaram et al., additional processing before and after the cleaving step forms a photovoltaic cell comprising semiconductor lamina 40, which is between about 0.2 and about 100 microns thick, for example between about 0.2 and about 50 microns, for example between about 1 and about 20 microns thick, in some embodiments between about 1 and about 10 microns thick or between about 5 and about 15 microns thick, though any thickness within the named range is possible. FIG. 2d shows the structure inverted, with receiver 60 at the bottom, as during operation in some embodiments. Receiver 60 may be a discrete receiver element having a maximum width no more than 50 percent greater than that of donor wafer 10, and preferably about the same width, as described in Herner, U.S. patent application Ser. No. 12/057265, “Method to Form a Photovoltaic Cell Comprising a Thin Lamina Bonded to a Discrete Receiver Element,” filed on Mar. 27, 2008, owned by the assignee of the present application and hereby incorporated by reference. Alternatively, a plurality of donor wafers may be affixed to a single, larger receiver, and a lamina cleaved from each donor wafer.

Using the methods of Sivaram et al., photovoltaic cells, rather than being formed from sliced wafers, are formed of thin semiconductor laminae without wasting silicon through kerf loss or by fabrication of an unnecessarily thick cell, thus reducing cost. The same donor wafer can be reused to form multiple laminae, further reducing cost, and may be resold after exfoliation of multiple laminae for some other use.

A variety of methods can be used to affix the donor wafer to the receiver element. Anodic bonding is often used to bond a silicon wafer to a glass receiver element, for example, and works by drawing sodium ions from the glass, making the surface of the glass highly reactive with the silicon. This technique relies on the chemical makeup of the glass, however, and may not be feasible with a receiver element made of some other material.

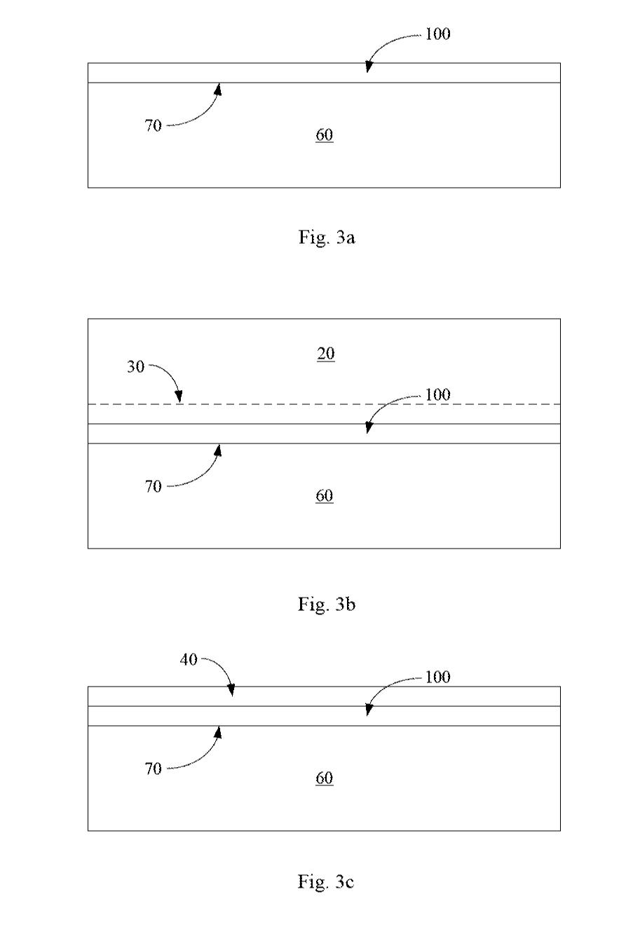

In the present invention, glass frit paste is used to permanently adhere a first surface of a donor wafer to a first surface of a receiver element in a device such as a photovoltaic cell. The glass frit paste can tolerate high temperature making it suitable for use during the fabrication of the device. Turning to FIG. 3a, in one embodiment, a mixture 100 containing glass frit such as a frit paste is applied to first surface 70 of receiver element 60. Receiver element 60 with frit paste 100 is heated, first to about 150-200 degrees C. to dry it, then to a higher temperature to burn out organics. The temperature required for burnout depends on the formulation of frit paste 100, but is typically at least 325 degrees C., for example 350-360 degrees C. Finally, in some embodiments, the structure is heated to the frit flow temperature, at which the glass frit flows under its own weight. These heating steps, and the prior drying step, may be performed in a continuous ramp, or the structure may be cooled between, or some other heating profile may be used. Following flow, the surfaces of donor wafer 20 and receiver element 60 are placed in contact, as shown in FIG. 3b, with frit paste 100 between them. Cleave plane 30 has previously been defined in donor wafer 20, for example by implantation of gas ions such as hydrogen and/or helium. Turning to FIG. 3c, upon applying heat and optional very light pressure to the structure, bonding is complete and lamina 40 cleaves from donor wafer 20.

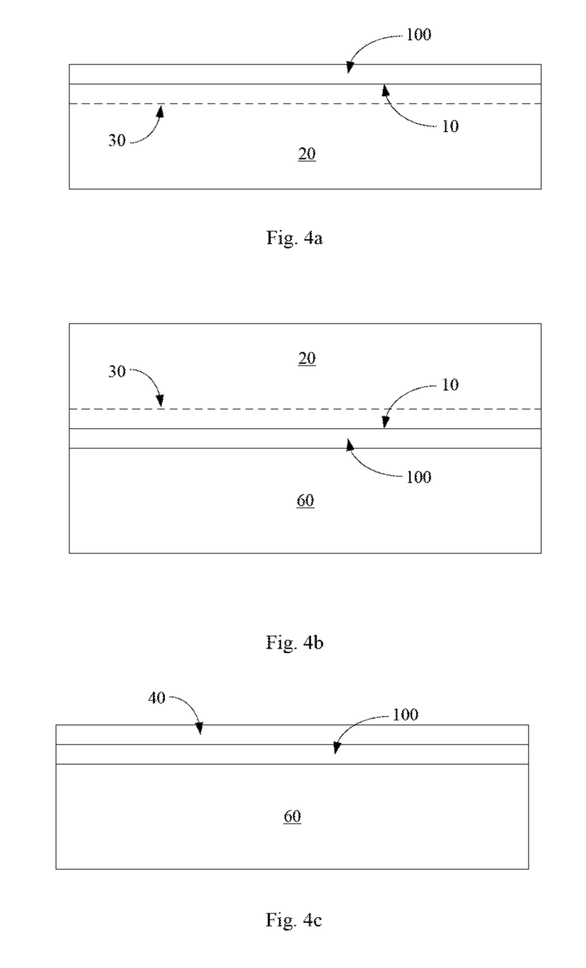

In an alternative embodiment, turning to FIG. 4a, frit paste 100 can be applied to first surface 10 of donor wafer 20, in which cleave plane 30 has been previously defined. Heating again is performed to dry the frit paste, for example between about 150 and 200 degrees C., and to drive off organics, at about 325 degrees C. or more. Heating may be performed in a single step or in separate steps. In this embodiment, the frit paste is not heated to flow temperature before affixing to the receiver element, because in most cases flow temperature will exceed the temperature at which the lamina will cleave from donor wafer 20. Turning to FIG. 4b, following drying and burn-out of organics, first surface 10 of donor wafer 20 is placed in contact with receiver element 60 with frit paste 100 between them. The structure is shown inverted, as it would be in some embodiments during fabrication. In FIG. 4c, a heating step completes adhesion of the structure and initiates exfoliation of lamina 40 at the cleave plane.

In another embodiment, glass frit paste may be applied to both the donor wafer and the receiver element. The donor wafer and receiver element are heated separately to dry and burn out organics, then placed in contact and heated to complete adhesion and exfoliate the lamina.

To summarize, what has been described is a method to fabricate a structure, the method comprising providing a semiconductor donor body, wherein a cleave plane has been defined within the donor body; providing a receiver element; applying a mixture containing glass frit to a first surface of the donor body, or to a first surface of the receiver element; heating the applied glass frit mixture to at least 325 degrees C.; after the step of heating the applied glass frit mixture, placing the first surface of the donor body and the first surface of the receiver element in contact, the heated glass frit mixture disposed between them; and heating the donor body and the receiver element, wherein, during this heating step, a lamina cleaves from the donor body at the cleave plane, the lamina remaining permanently adhered to the receiver element. The lamina is suitable for use in a photovoltaic cell, and such a photovoltaic cell may be fabricated, the cell comprising the lamina.

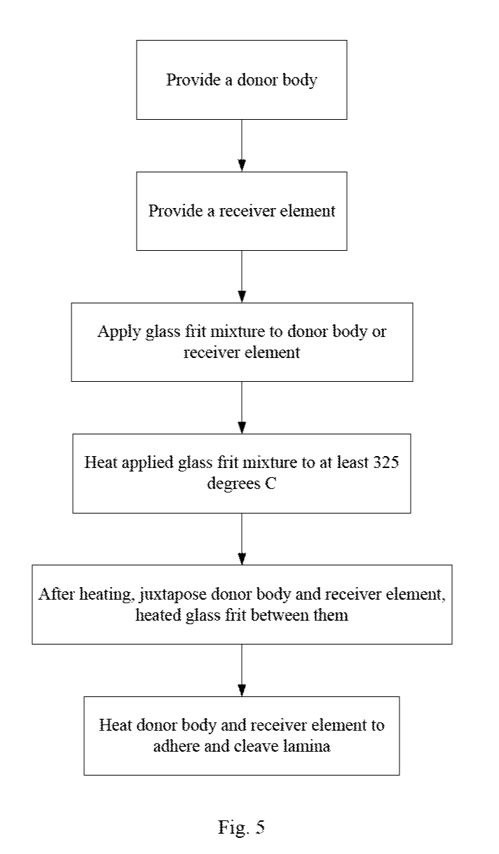

These steps are illustrated in the flow chart of FIG. 5.

In some embodiments, during the step of heating the applied glass frit mixture, the peak temperature of this heating step is at least the approximate flow temperature of the glass frit mixture. The peak temperature of this heating step is between about 650 degrees C. and about 900 degrees C.

Glass frit offers several advantages as a binder that promotes adhesion. Most adhesives will densify and continue to outgas volatiles as temperature is increased. Once the donor wafer and the receiver element are in contact, with the frit paste layer between them, volatiles cannot escape. Trapped volatiles would form bubbles, resulting in cracks and pinholes in the lamina. In contrast, after burn-out of organics is complete, glass frit paste does not continue to outgas volatiles. Glass frit is stable and will not continue to densify with increasing temperature. The lamina may be very thin, for example 1 to 20, 1 to 10 or 1 to 5 microns. Densification of an adhesive between the lamina and the receiver element would put stress on the very thin lamina, possibly causing cracking or other damage. As will be seen, in some embodiments the structure will, in subsequent steps, be subjected to high temperatures, for example about 950 degrees C. Thus an adhesive that does not experience outgassing or densification at such temperatures is highly advantageous. Further, glass frit bonds readily to uneven surfaces, allowing the use of unpolished receiver elements, which may be lower cost. That a pristine surface is not essential also relaxes the requirements on the donor wafer, and its preparation for reuse following cleaving of a first lamina. Finally, the glass frit bond is robust and highly resistant to subsequent wet processing, which may include exposure to etchants such as KOH.

For clarity, detailed examples of a photovoltaic assembly including a lamina having thickness between 0.2 and 100 microns, in which the lamina is adhered to a receiver element using glass frit paste, according to embodiments of the present invention, will be provided. For completeness, many materials, conditions, and steps will be described. It will be understood, however, that many of these details can be modified, augmented, or omitted while the results fall within the scope of the invention.

### Example

### Frit Paste Applied to Receiver Element

The process begins with a donor body of an appropriate semiconductor material. An appropriate donor body may be a monocrystalline silicon wafer of any practical thickness, for example from about 200 to about 1000 microns thick. Typically the wafer has a <100> orientation, though wafers of other orientations may be used. In alternative embodiments, the donor wafer may be thicker; maximum thickness is limited only by practicalities of wafer handling. Alternatively, polycrystalline or multicrystalline silicon may be used, as may microcrystalline silicon, or wafers or ingots of other semiconductor materials, including germanium, silicon germanium, or III-V or II-VI semiconductor compounds such as GaAs, InP, etc. In this context the term multicrystalline typically refers to semiconductor material having grains that are on the order of a millimeter or larger in size, while polycrystalline semiconductor material has smaller grains, on the order of a thousand angstroms. The grains of microcrystalline semiconductor material are very small, for example 100 angstroms or so. Microcrystalline silicon, for example, may be fully crystalline or may include these microcrystals in an amorphous matrix. Multicrystalline or polycrystalline semiconductors are understood to be completely or substantially crystalline. It will be appreciated by those skilled in the art that the term “monocrystalline silicon” as it is customarily used will not exclude silicon with occasional flaws or impurities such as conductivity-enhancing dopants.

The process of forming monocrystalline silicon generally results in circular wafers, but the donor body can have other shapes as well. For photovoltaic applications, cylindrical monocrystalline ingots are often machined to an octagonal, or pseudosquare, cross section prior to cutting wafers. Wafers may also be other shapes, such as square. Square wafers have the advantage that, unlike circular or hexagonal wafers, they can be aligned edge-to-edge on a photovoltaic module with minimal unused gaps between them. The diameter or width of the wafer may be any standard or custom size. For simplicity this discussion will describe the use of a monocrystalline silicon wafer as the semiconductor donor body, but it will be understood that donor bodies of other types and materials can be used.

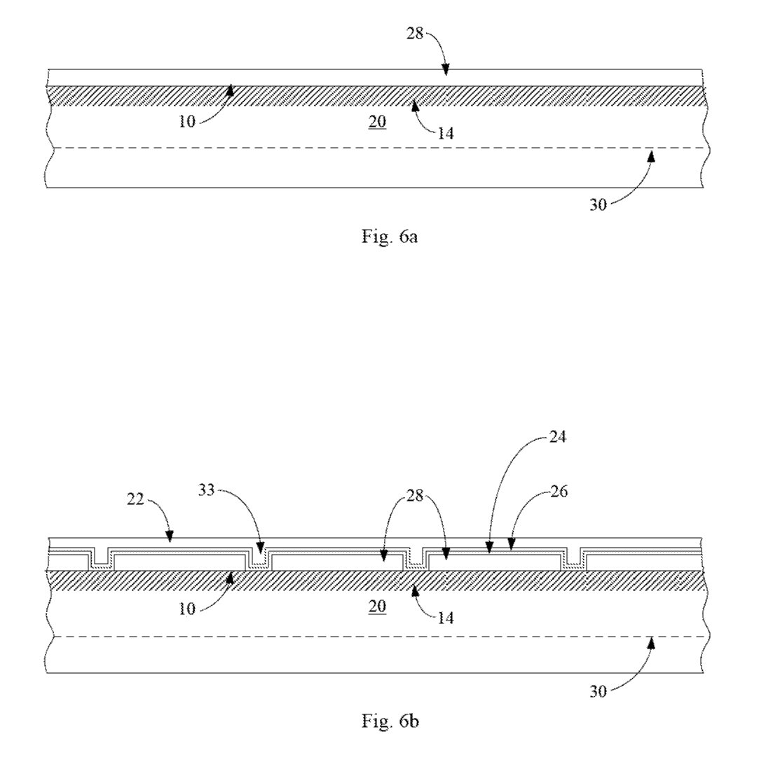

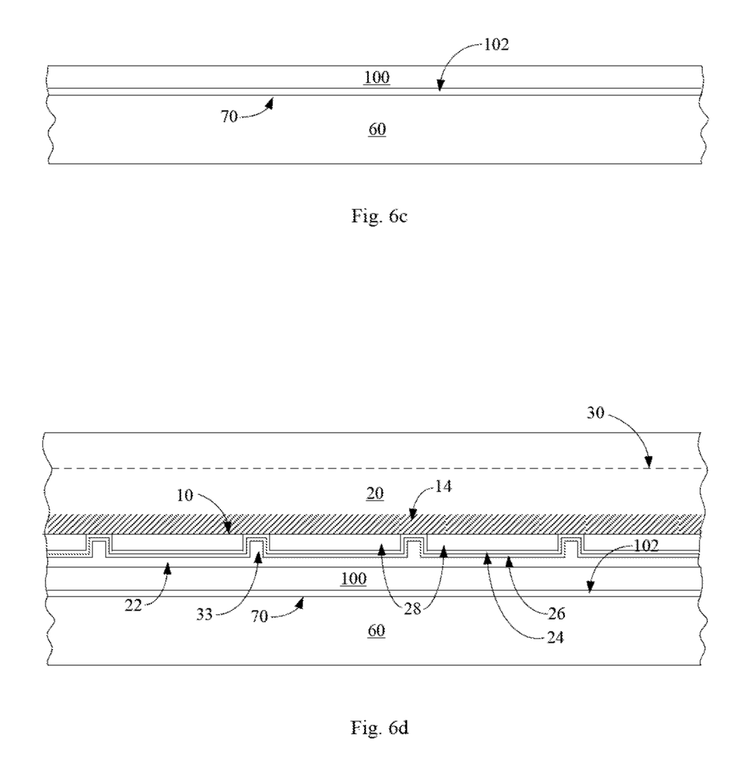

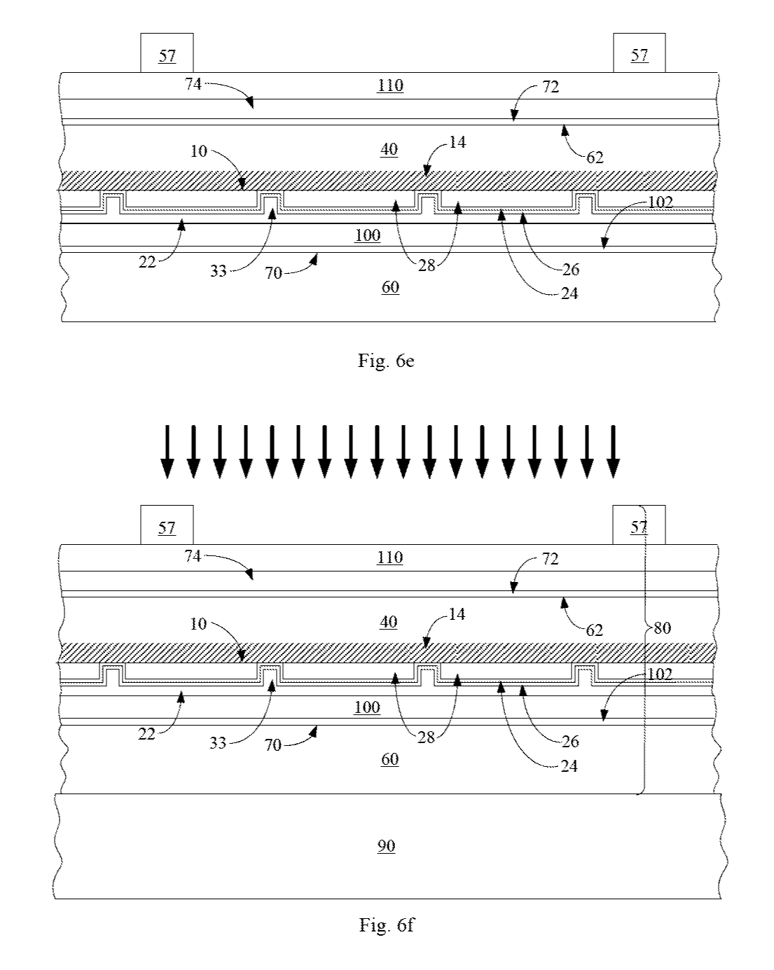

Referring to FIG. 6a, donor wafer 20 is a monocrystalline silicon wafer which is lightly to moderately doped to a first conductivity type. The present example will describe a relatively lightly p-doped wafer 20 but it will be understood that in this and other embodiments the dopant types can be reversed. Wafer 20 may be doped to a concentration of between about 1×10¹⁵ and about 1×10¹⁸ dopant atoms/cm³, for example about 1×10¹⁷ dopant atoms/cm³. Donor wafer 20 may be, for example, solar- or semiconductor-grade silicon.

First surface 10 may be heavily doped to some depth to the same conductivity type as wafer 20, forming heavily doped region 14; in this example, heavily doped region 14 is p-type. This doping step can be performed by any conventional method, including diffusion doping. Any conventional p-type dopant may be used, such as boron. Dopant concentration may be as desired, for example at least 1×10¹⁸ dopant atoms/cm³, for example between about 1×10¹⁸ and 1×10²¹ dopant atoms/cm³. Doping and texturing can be performed in any order, but since most texturing methods remove some thickness of silicon, it may be preferred to form heavily doped p-type region 14 following texturing. Heavily doped region 14 will provide electrical contact to the base region in the completed device. In an alternative embodiment, heavily doped region 14 can be n-type, forming a p-n junction between heavily doped region 14 and the rest of lightly doped wafer 20. In this embodiment, heavily doped region 14 will be the emitter of the cell to be formed.

Next, in the present embodiment, a dielectric layer 28 is formed on first surface 10. As will be seen, in the present example first surface 10 will be the back of the completed photovoltaic cell, and a conductive material is to be formed on dielectric layer 28. The reflectivity of the conductive layer to be formed is enhanced if dielectric layer 28 is relatively thick. For example, if dielectric layer 28 is silicon dioxide, it may be between about 1000 and about 2000 angstroms thick, while if dielectric layer 28 is silicon nitride, it may be between about 700 and about 800 angstroms thick, for example about 750 angstroms. This layer may be grown or deposited by any suitable method. A grown oxide or nitride layer 28 passivates first surface 10 better than if this layer is deposited. In some embodiments, a first thickness of dielectric layer 28 may be grown, while the rest is deposited.

Turning to FIG. 6b, in the next step, ions, preferably hydrogen or a combination of hydrogen and helium, are implanted into wafer 20 through first surface 10 to define cleave plane 30, as described earlier. This implant may be performed using the teachings of Parrill et al., U.S. patent application Ser. No. 12/122108, “Ion Implanter for Photovoltaic Cell Fabrication,” filed May 16, 2008; or those of Ryding et al., U.S. patent application Ser. No. 12/494,268, “Ion Implantation Apparatus and a Method for Fluid Cooling,” filed Jun. 30, 2009; or of Purser et al. U.S. patent application Ser. No. 12/621,689, “Method and Apparatus for Modifying a Ribbon-Shaped Ion Beam,” filed Nov. 19, 2009, all owned by the assignee of the present invention and hereby incorporated by reference. The overall depth of cleave plane 30 is determined by several factors, including implant energy. The depth of cleave plane 30 can be between about 0.2 and about 100 microns from first surface 10, for example between about 0.5 and about 20 or about 50 microns, for example between about 1 and about 10 microns, between about 1 or 2 microns and about 5 or 6 microns, or between about 4 and about 8 microns. Alternatively, the depth of cleave plane 30 can be between about 5 and about 15 microns, for example about 11 or 12 microns.

Still referring to FIG. 6b, after implant, openings 33 are formed in dielectric layer 28 by any appropriate method, for example by laser scribing or screen printing an etchant paste. The size of openings 33 may be as desired, and will vary with dopant concentration, metal used for contacts, etc. In one embodiment, these openings may be about 40 microns square. Note that figures are not to scale.

A conductive layer 24 is formed on dielectric layer 28 by any suitable method, for example by sputtering or thermal evaporation. Conductive layer 24 should be conductive, reflective, and able to tolerate relatively high temperatures to follow. Titanium is a suitable choice, with the additional advantage that, during subsequent heating steps, titanium in contact with silicon in openings 33 will form titanium silicide, providing a good electrical contact. This layer may have any desired thickness, for example between about 30 and about 400 angstroms, in some embodiments about 200 angstroms thick or less, for example about 50 angstroms. Layer 24 may be titanium, cobalt or an alloy thereof, for example, an alloy which is at least 80 or 90 atomic percent titanium or cobalt. Titanium layer 24 is in immediate contact with first surface 10 of donor wafer 20 through openings 33 in dielectric layer 28; elsewhere it contacts dielectric layer 28. In alternative embodiments, dielectric layer 28 is omitted, and titanium layer 24 is formed in immediate contact with donor wafer 20 at all points of first surface 10.

Non-reactive barrier layer 26 is formed on and in immediate contact with titanium layer 24. This layer is formed by any suitable method, for example by sputtering or thermal evaporation. Non-reactive barrier layer 26 may be any material, or stack of materials, that will not react with silicon, is conductive, and will tolerate the higher temperatures used in subsequent processing. This layer may also serve as a barrier to additives in the frit paste to be applied in a later step. Suitable materials for non-reactive barrier layer include Mo, W, TiN, TiW, TiO, Ta, TaN, TaO, TaSiN, Zr, or alloys thereof. The thickness of non-reactive barrier layer 26 may range from, for example, between about 50 and about 200 angstroms, for example between about 50 and about 100 angstroms. In some embodiments this layer is about 100 angstroms thick.

Low-resistance layer 22 is formed on non-reactive barrier layer 26. This layer may be, for example, titanium, cobalt, silver, or tungsten or alloys thereof. In this example low-resistance layer 22 is titanium or an alloy that is at least 80 or 90 atomic percent titanium, formed by any suitable method. Titanium layer 22 may be between about 500 and about 10,000 angstroms (1 micron) thick, for example about 3000 angstroms thick.

A Ti—Mo—Ti stack including layers 24, 26, and 22 has been described. In other embodiments there may be multiple thin layers of the non-reactive barrier material, in this example Mo, interposed with the other conductive layers, for example a Ti—Mo—Ti—Mo—Ti stack.

Turning to FIG. 6c, receiver element 60 is prepared separately. Receiver element 60 will provide structural support for the lamina to be formed. A variety of materials can be used for receiver element 60, including silicon, for example metallurgical silicon; metal such as stainless steel; high-temperature glass; or conductive ceramic. A low-grade wafer of sintered silicon may be a suitable receiver element. In some embodiments receiver element 60 is conductive, while in others it may be of a dielectric material. Receiver element 60 may be a laminate or a composite, including several materials. The frit mixture to be used will adhere effectively to either a smooth or a rough surface, for example a surface having a roughness of about 3 microns is readily tolerated.

Receiver element 60 may be about the same size as donor wafer 20, or slightly larger, or slightly smaller, and may or may not be the same shape. In some embodiments, receiver element 60 has a much larger area than donor wafer 20, and a plurality of donor wafers are affixed, side-by-side, to a single receiver element 60.

It may be preferred to form an adhesion layer 102, for example of titanium or another suitable material, on first surface 70 before applying the glass frit mixture. This layer may be, for example, about 3000 angstroms thick, and may be formed by sputtering, evaporation, or some other method. In one embodiment, for example, receiver element 60 is a metallurgical silicon wafer, which may be heavily doped and thus conductive. In an alternative embodiment, an oxide layer (not shown) may be grown or otherwise formed on its surface before titanium layer 102 is formed. Titanium layer 102 may contact receiver element 60 through openings in the oxide layer.

A layer 100 of glass frit paste is applied to first surface 70 of receiver element 60. Frit paste is a mixture containing an organic binder, a solvent, and an inorganic frit. Many formulations are commercially available. The organic binder can be ethyl cellulose, and the solvent can be, for example, terpineol or glycol ether. The glass particles can be borosilicate glass, lead borosilicate glass, lead oxide glass, barium borosilicate glass, zinc oxide glass, magnesium oxide glass, zinc borosilicate glass, magnesium borosilicate glass, strontium borosilicate glass, bismuth oxide glass, zirconium oxide glass, aluminum oxide glass, cadmium oxide glass, calcium borosilicate glass, palladium oxide glass, tin oxide glass, copper oxide glass, chromium oxide glass, alkali metal (K, Na, or Li) borosilicate glass, etc. Mixtures of various borosilicate and metal oxide glass compounds are often used in one paste. Lead borosilicate vitreous glass frit, for example, may be an advantageous choice. A glass frit that has excellent surface flatness when fired is advantageous. Average frit particle size may be about less than a micron to about 5 microns across, or up to 10 microns, and may be vitreous or crystallizing; either type may be used. An average glass frit particle size that is about 0.7 or 0.8 microns may be advantageous. In some embodiments, the frit paste formulation can be loaded with metal particles to make the paste conductive. The particles can be, for example, silver, nickel, or titanium, either of powder or flake morphology, or some other metal. The metal particle percentage may be up to 30 percent of the paste by volume.

The thickness of layer 100 of frit paste may be as desired, and may vary depending on the frit formulation. Layer 100 may be, for example, about 8-10 microns thick before firing, with a post-firing thickness of 4-5 microns. Frit paste layer 100 can be screen printed, where the screen excludes the outermost edge of first surface 70, for example the outer 0.5 or 0.4 mm.

Following application of frit paste layer 100, receiver element 60 is heated, for example at about 150-200 degrees C. for about 2 to about 10 minutes, for example about 4 to 5 minutes. This heating step dries the mixture, driving off solvents. Heating at about 325 degrees C. or above, for example about 350 or about 360 degrees C. or above, will generally be sufficient to burn out the organic binder. Drying to drive off solvents and burnout of organics can be performed as separate steps, or temperature may be continuously ramped. The best adhesion may be achieved by continued heating to the flow temperature, at which the glass frit begins to flow under its own weight. Flow temperature depends on the formulation of the frit, and may be, for example, between about 650 and about 900 degrees C., for example between about 680 and about 880 degrees C., for example between about 700 and about 760 degrees C. Cooling may be done slowly to minimize stress.

Turning to FIG. 6d, first surface 70 of receiver element 60 and first surface 10 of donor wafer 20 are brought in contact. In the embodiment shown, the intermetal, of titanium layer 24, molybdenum layer 26, and titanium layer 22, as well as dielectric 28, frit paste layer 100, and titanium layer 102, are disposed between them.

To permanently adhere the structure, heat is applied. This heating step will generally also cause exfoliation of a lamina at cleave plane 30. In the embodiment shown in FIG. 6d, receiver element 60 and donor wafer 20, with interposed layers, are heated to a temperature which is at least the flow temperature of the frit. For example, for a frit having a flow temperature around 700 degrees C., the temperature of this exfoliation/bonding step may be about 800 or 830 degrees C. For other frit formulations, this step may be performed between about 650 and 880 degrees C., and in some cases up to 950 degrees C. Care should be taken to make sure heating occurs evenly across the wafer. On a belt furnace, for example, wafers should enter the heated area quickly, lest exfoliation begin non-uniformly across the wafer. This heating step may take place in air. Exfoliation will generally take place before peak temperature is reached. Very light pressure may be applied during this step to keep the structure from separating before bonding is completed. A light weight, providing, for example, about 0.05 to 2 psi, for example about 0.5 psi, is generally sufficient. A quartz jig or a small stack of wafers may provide adequate pressure.

In some embodiments, for example, a two-piece quartz fixture including a base and a lid may be used. The fixture may be flame-polished quartz, the base having a cutout or pocket shaped to securely hold the receiver element and donor wafer, while the lid has a boss which fits into the pocket of the base. The quartz fixture may be preheated to a temperature below the ultimate temperature used to adhere the donor wafer and the receiver element and to cleave the lamina from the donor wafer. In one example in which adhering and cleaving occur during a heating step in a furnace with a peak temperature of about 830 degrees C., the quartz fixture may be at about 500 degrees C. when the unheated donor wafer and receiver element are placed into it. It is thought that preheating the quartz fixture allows the receiver element and donor wafer to reach near-exfoliation temperature uniformly. In contrast, when a room-temperature receiver element and donor wafer move into the hot zone of a radiation lamp belt furnace, the leading edge is heated first and the trailing edge last, causing non-uniform exfoliation. Similar results may be achieved by heating the structure slowly and uniformly in a box furnace without the use of a preheated fixture.

During the heating step which permanently adheres the receiver element and the donor wafer, the receiver element and the donor wafer are stacked vertically one atop the other. Either the donor wafer is above the receiver element, or the receiver element is above the donor wafer. It has been found that when the receiver element is a textured silicon wafer, results may be better when the receiver element is on top, as compared to when the receiver element is not textured.

The structure is then cooled. Cooling may be performed slowly, for example at about 1 degree per second. Turning to FIG. 6e, exfoliation is complete, and following cooling, lamina 40 can be easily separated from the donor wafer, for example using suction or some other method.

During relatively high-temperature steps, such as the exfoliation of lamina 40, the portions of titanium layer 24 in immediate contact with silicon lamina 40 will react to form titanium silicide. If dielectric layer 28 was included, titanium silicide is formed where first surface 10 of lamina 40 was exposed in vias 33. If dielectric layer 28 was omitted, in general all of the titanium of titanium layer 24 will be consumed, forming a blanket of titanium silicide.

Depending on its formulation, frit layer 100 may or may not be conductive. Metal additives may be included to make frit layer 100 more conductive, and note that during heating, some titanium from titanium layers 22 and 102 will migrate into frit layer 100, causing it to be more conductive. In some embodiments, one or more intermediate layers of titanium or some other metal, or some other conductive element, may be included within frit paste layer 100 to enhance its conductivity.

Second surface 62 has been created by exfoliation. At this point texturing can be created at second surface 62 according to embodiments of the present invention. A standard clean is performed at second surface 62, for example by hydrofluoric acid.

A method for forming advantageous low-relief texture is disclosed in Li et al., U.S. patent application Ser. No. 12/729,878, “Creation of Low-Relief Texture for a Photovoltaic Cell,” filed Mar. 23, 2010, owned by the assignee of the present invention and hereby incorporated by reference.

In some embodiments, conductivity of the glass frit may be enhanced by performing an anneal in a forming gas, a mixture of nitrogen and hydrogen. The percentage of H₂ may be, for example, between about 3 and about 15 percent, for example about 10 percent. The anneal may be performed at between about 350 and 500 degrees C., for example at about 400 degrees C. This anneal may be particularly useful when metal precipitates such as lead or bismuth are present in the frit, and is performed following exfoliation. If an amorphous layer is to be formed on second surface 62, as will be described, this anneal should be performed before its formation.

In some embodiments, an additional anneal may be performed to repair damage caused to the crystal lattice throughout the body of lamina 40 during the implant step Annealing may be performed, for example, at 500 degrees C. or greater, for example at 550, 600, 650, 700, 800, 850 degrees C. or greater, at about 950 degrees C. or more. The structure may be annealed, for example, at about 650 degrees C. for about 45 minutes, or at about 800 degrees for about two minutes, or at about 950 degrees for 60 seconds or less. In many embodiments the temperature exceeds 900 degrees C. for at least 30 seconds. In other embodiments, no damage anneal is performed.

Referring to FIG. 6e, if any native oxide (not shown) has formed on second surface 62 during annealing, it may be removed by any conventional cleaning step, for example by hydrofluoric acid. After cleaning, a silicon layer is deposited on second surface 62. This layer 74 includes heavily doped silicon, and may be amorphous, microcrystalline, nanocrystalline, or polycrystalline silicon, or a stack including any combination of these. This layer or stack may have a thickness, for example, between about 50 and about 350 angstroms. FIG. 6e shows an embodiment that includes intrinsic amorphous silicon layer 72 between second surface 62 and doped layer 74. In other embodiments, layer 72 may be omitted. In this example, heavily doped silicon layer 74 is heavily doped n-type, opposite the conductivity type of lightly doped p-type lamina 40, and serves as the emitter of the photovoltaic cell being formed, while lightly doped p-type lamina 40 comprises the base region. If included, layer 72 is sufficiently thin that it does not impede electrical connection between lamina 40 and doped silicon layer 74. Note that in general deposited amorphous silicon is conformal; thus the texture at surface 62 is reproduced at the surfaces of silicon layers 72 and 74.

A transparent conductive oxide (TCO) layer 110 is formed on heavily doped silicon layer 74. Appropriate materials for TCO 110 include indium tin oxide, as well as aluminum-doped zinc oxide, tin oxide, titanium oxide, etc.; this layer may be, for example, about 1000 angstroms thick, and serves as both a top electrode and an antireflective layer. In alternative embodiments, an additional antireflective layer (not shown) may be formed on top of TCO 110.

A photovoltaic cell has been formed, including lightly doped p-type lamina 40, which comprises the base of the cell, and heavily doped n-type amorphous silicon layer 74, which serves as the emitter of the cell. Heavily doped p-type region 14 will provide good electrical contact to the base region of the cell. Electrical contact must be made to both faces of the cell. Contact to emitter 74 is made, for example, by gridlines 57. If receiver element 60 is conductive, it has been formed in electrical contact with heavily doped region 14 by way of conductive layers 24, 26, and 22.

If receiver element 60 is not conductive, electrical contact to heavily doped region 14 can be formed using a variety of methods, including those described in Petti et al., U.S. patent application Ser. No. 12/331,376, “Front Connected Photovoltaic Assembly and Associated Methods,” filed Dec. 9, 2008; and Petti et al., U.S. patent application Ser. No. 12/407,064, “Method to Make Electrical Contact to a Bonded Face of a Photovoltaic Cell,” filed Mar. 19, 2009, hereinafter the '064 application, both owned by the assignee of the present application and both hereby incorporated by reference.

FIG. 6f shows completed photovoltaic assembly 80, which includes a photovoltaic cell and receiver element 60. In alternative embodiments, by changing the dopants used, heavily doped region 14 may serve as the emitter, at first surface 10, while heavily doped silicon layer 74 serves as a contact to the base region. Incident light (indicated by arrows) falls on TCO 110, enters the cell at heavily doped n-type amorphous silicon layer 74, enters lamina 40 at second surface 62, and travels through lamina 40. Reflective layer 24 will serve to reflect some light back into the cell. In this embodiment, receiver element 60 serves as a substrate. Receiver element 60 and lamina 40, and associated layers, form a photovoltaic assembly 80. Multiple photovoltaic assemblies 80 can be formed and affixed to a supporting substrate 90 or, alternatively, a supporting superstrate (not shown). Each photovoltaic assembly 80 includes a photovoltaic cell. The photovoltaic cells of a module are generally electrically connected in series.

In the present example, the body of lamina 40, which serves as the base region of the cell, was lightly doped p-type, amorphous silicon layer 74 at second surface 62 was heavily doped n-type, forming the emitter of the cell, and heavily doped region 14, at first surface 10, was heavily doped p-type, providing a base contact region. If frit mixture 100 includes boron, some of that boron may diffuse from frit mixture 100 into lamina 40 at first surface 10, into region 14 adjacent first surface 10. With a boron-based frit, then, it may be advantageous for this region to be p-doped, as additional p-type dopant will be provided by the frit. In some embodiments, it may not be necessary to provide doping, for example by diffusion doping, at first surface 10 before frit mixture 100 is applied, as the boron diffusing from frit mixture 100 may provide sufficient p-type doping for a back-surface field or for a back-junction formation.

In alternative embodiments all polarities could be reversed.

### Example

### Frit Paste Applied to Donor Wafer

In the previous example, frit paste was applied to the receiver element before it was affixed to the donor wafer. In an alternative process, frit paste may be applied first to the donor wafer.

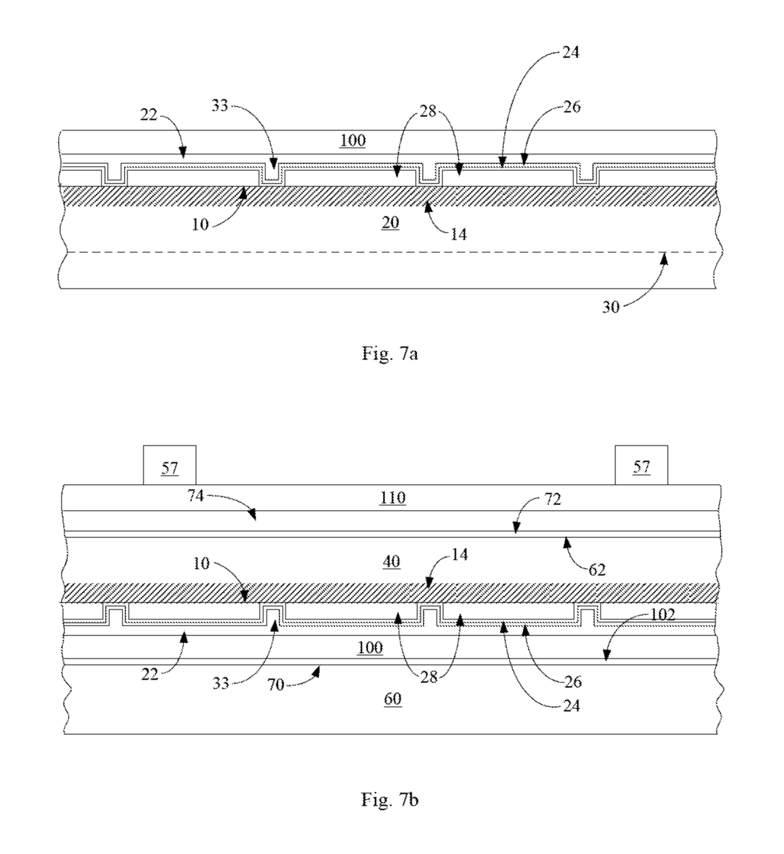

Turning to FIG. 7a, donor wafer 20 has been prepared as in the prior example, with heavily doped region 14 and cleave plane 30 defined in wafer 20, and dielectric layer 28 and conductive layers 24, 26, and 22 formed on first surface 10.

Frit paste layer 100 is applied over first surface 10, in contact with titanium layer 22. It has been found that the wetting behavior of frit paste is favorable with titanium and that these materials adhere well. The type and thickness of frit paste layer 100 may be as in the prior embodiment.

The structure is heated to about 150 to 200 degrees C. for, for example, between about 2 and about 10 minutes, for example between about 4 and about 5 minutes, to dry the frit paste and drive off solvents.

Following drying, a second heating step burns out the organics from frit paste layer 100. The structure may be cooled between these heating steps, or temperature may be continuously ramped, or other heating profiles may be used. Temperature should be kept below a point and duration that will cause exfoliation of the lamina. Burnout may be accomplished at, for example, between about 325 and about 385 degrees C., for example between about 350 and about 375 degrees C., for example about 360 degrees C., for example from a few seconds to a minute. In this embodiment, frit paste layer 100 will not be heated to its flow temperature before donor wafer 20 is joined to the receiver element, as flow temperature will generally cause exfoliation. For this reason, a crystallizing (de-vitrifying) glass frit may be most suitable for application to the donor wafer. Once organics have been burned out, frit paste layer 100 will undergo no additional outgassing or densification. Outgassing will produce voids in the lamina to be formed, while densification will stress the lamina, possibly causing fractures; thus both are to be avoided once the donor wafer and the receiver element have been juxtaposed, and once the lamina as been cleaved from the donor wafer.

Turning to FIG. 7b, following burnout of organics, donor wafer 20 and its associated layers are joined with first surface 70 of receiver element 60. As in the previous example, titanium layer 102 may have been formed on first surface 70 before the surfaces are brought in contact; thus dielectric layer 28, conductive layers 24, 26, and 22, frit paste layer 100, and titanium layer 102 are disposed between first surface 10 of donor wafer 20 and first surface 70 of donor wafer 60. An oxide layer, not shown, may have been formed on receiver element 60 before formation of titanium layer 102. A weight to apply light pressure, for example 0.05-4 psi, for example 2 psi, is applied, and the structure is heated as in the prior embodiment to permanently adhere the structure and to cleave lamina 40 from the donor wafer at the cleave plane.

The structure is cooled, and lamina 40 is separated from the donor wafer and is textured and annealed, all as taught previously. The structure shown in FIG. 6e is created by formation of intrinsic amorphous silicon layer 72, heavily doped amorphous silicon layer 74, and TCO layer 110 as described earlier, and gridlines 57 provide electrical contact to heavily doped amorphous silicon layer 74.

Other variations are possible, as will be understood by those skilled in the art when informed by the teachings of the present specification. Frit paste can be applied to both the donor wafer and the receiver element, and heated to drive off solvents and burn out organics before being placed in contact with each other.

As mentioned, the receiver element may be formed of materials including semiconductor (metallurgical silicon, for example), metal (stainless steel, etc.), metal compounds, or ceramic. If the receiver element is conductive, electrical contact to heavily doped region 14, which may be either the emitter or the base contact, depending on the conductivity types used, is straightforward. If the receiver element is a doped silicon wafer, for example, a metal layer may be formed on the back surface, for example an aluminum layer formed by sputtering, evaporation, or some other suitable method. One or more busbars is then added, for example by screenprinting, for electrical contact.

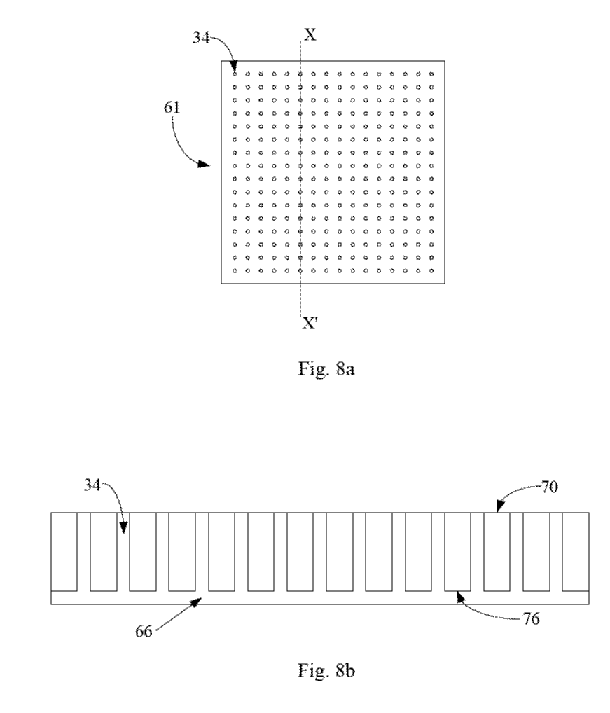

Many ceramics are inexpensive, sturdy, can tolerate high temperature, and have a coefficient of thermal expansion that is similar to that of silicon (this last trait minimizes stress on the lamina.) Without additives, though, ceramics are not conductive. A suitable receiver element may be a dielectric or insufficiently conductive ceramic body which is perforated. FIG. 8a shows such a receiver element 61 in a plan view, while FIG. 8b shows a cross-section at X-X′. A conductive material 66, which may be applied using any suitable method such as sputtering or printing, fills holes 34 and back surface 76 of ceramic body 61 before frit paste layer is applied to first surface 70. Conductive material 66 can be, for example, silver, copper, aluminum, nickel, or titanium paste with filler.

In another embodiment, following fabrication of a photovoltaic assembly as described, a conductive material layer such as aluminum may be formed on the back surface of a non-conductive receiver element, in one embodiment by screen printing aluminum, for example 30 to 50 mm thick. Laser holes are then fired through the aluminum layer to the frit layer. This drives aluminum through the receiver element into the glass frit, making it conductive. This step may be preformed following deposition of TCO layer onto the light-facing surface, following all wet chemical processing. Depending on the degree of conductivity desired and the materials used, about 5,000 to 150,000 laser holes, in one embodiment about 25,000 holes, for example, can be made for a pseudosquare receiver element having an area of 156 cm². (The term “pseudosquare” describes a square wafer with clipped corners typically used in the solar industry.) Using current laser technology, this number of holes can be made in seconds. Distance between laser holes may be, for example, from about 250 to about 2000 microns.

In the examples provided, the receiver element serves as a substrate in the finished device, with incident light entering the cell at the cleaved surface, and passing through the lamina before reaching a reflective layer at the back of the cell. In alternative embodiments, the receiver element could serve as a superstrate in the completed device, in which incident light falls first on the receiver element, passes through it and enters the lamina at the affixed surface, then passes through the lamina. The receiver element would need to be formed of a transparent material able to tolerate high temperature, and the glass frit and associated layers disposed between the receiver element and the lamina would need to be formed of materials that are transparent or nearly so.

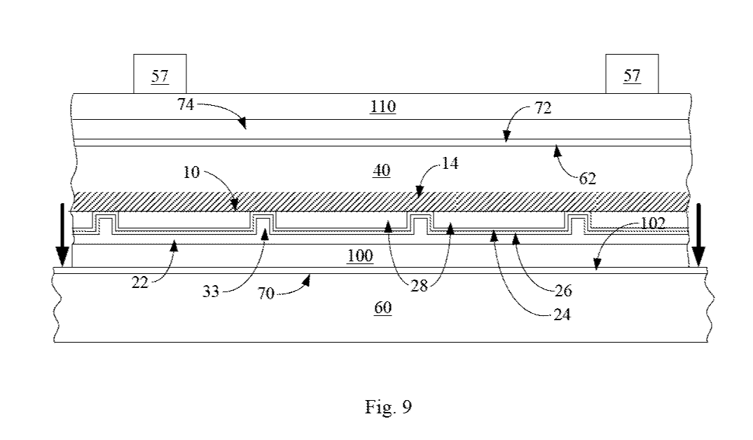

In other embodiments, turning to FIG. 9, a dielectric receiver element 60 may have a slightly larger widest dimension than the widest dimension of the lamina 40 (and of the donor wafer from which it was formed.) If a conductive layer 102 is formed on receiver element 60 before frit paste layer 100 is formed, and if the frit formulation includes additives to make it conductive, electrical contact to heavily doped region 14 can be made by way of the exposed rim of conductive layer 102, marked with arrows. Heavily doped region 14 is the emitter of the cell or the base contact of the cell.

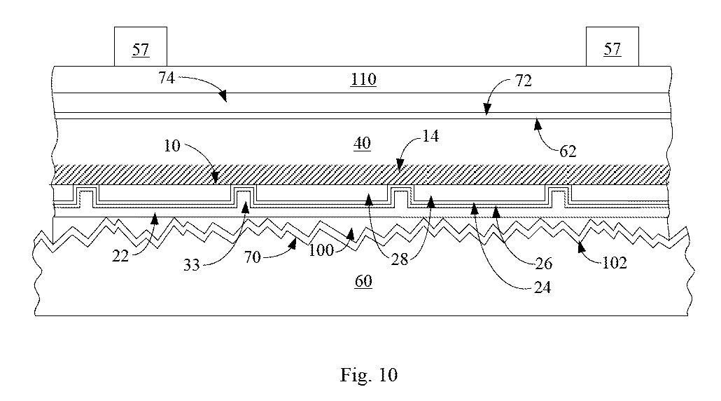

In yet another embodiment, shown in FIG. 10, receiver element 60 may be textured. Titanium layer 102 (or some other metal) is formed on receiver element surface 70. In the example shown, receiver element 60 may be metallurgical grade silicon, and the texturing can be produced by etching using KOH or some other suitable etchant. The pyramids will be irregular, and their rough average pitch may be about 6 microns, while rough peak-to-valley height may be about 2 to about 8 microns. Glass frit mixture 100 will tend to flow and settle between the pyramids. In some areas, the irregular pyramids may contact titanium layer 22, achieving good electrical contact to heavily doped region 14. Other materials can be used for receiver element 60, and other methods can be used to form peaks, spikes or other protrusions from the surface of receiver element 70, including chemical or mechanical means, or by laser texturing.

A variety of embodiments has been provided for clarity and completeness. Clearly it is impractical to list all possible embodiments. Other embodiments of the invention will be apparent to one of ordinary skill in the art when informed by the present specification. Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A method to fabricate a structure, the method comprising:
providing a semiconductor donor body, wherein a cleave plane has been defined within the donor body;
providing a receiver element;
applying a mixture containing glass frit to a first surface of the donor body or to a first surface of the receiver element;
heating the applied glass frit mixture to at least 325 degrees C.;
after the step of heating the applied glass frit mixture, placing the first surface of the donor body and the first surface of the receiver element in contact, the heated glass frit mixture disposed between them; and
heating the donor body and the receiver element, wherein, during this heating step, a lamina cleaves from the donor body at the cleave plane, the lamina remaining permanently adhered to the receiver element.

2. The method of claim 1 wherein the lamina has a thickness between about 1 micron and about 20 microns.

3. The method of claim 2 wherein the lamina has a thickness between about 4 microns and about 8 microns.

4. The method of claim 1 wherein the lamina is suitable for use in a photovoltaic cell.

5. The method of claim 4 further comprising fabricating a photovoltaic cell, the photovoltaic cell comprising the lamina.

6. The method of claim 5 wherein the lamina comprises the base region of the photovoltaic cell.

7. The method of claim 6 wherein the receiver element has a widest dimension and the donor body has a widest dimension, the widest dimension of the receiver element larger than the widest dimension of the donor body, wherein the photovoltaic cell comprises an emitter and a base region, wherein electrical contact is made to the base region contact or to the emitter of the photovoltaic cell by way of a conductive layer disposed between the receiver element and the donor body.

8. The method of claim 1 further comprising heating the adhered lamina and receiver element to at least 850 degrees C.

9. The method of claim 8 further comprising heating the adhered lamina and receiver element to at least 900 degrees C.

10. The method of claim 1 wherein the receiver element is conductive.

11. The method of claim 1 wherein the receiver element comprises metallurgical grade silicon.

12. The method of claim 1 wherein the receiver element comprises stainless steel.

13. The method of claim 1 wherein the receiver element comprises ceramic.

14. The method of claim 13 wherein the receiver element is perforated ceramic, a conductive material filling the perforations.

15. The method of claim 1 wherein the glass frit mixture is applied to the first surface of the receiver element, and wherein, during the step of heating the applied glass frit mixture, the peak temperature of this heating step is at least the approximate flow temperature of the glass frit mixture.

16. The method of claim 15 wherein the peak temperature of this heating step is between about 650 degrees C. and about 900 degrees C.

17. The method of claim 1 wherein, during the step of heating the donor body and the receiver element, the peak temperature is between about 650 and about 900 degrees C.

18. The method of claim 1 wherein, in the completed structure, the glass frit mixture includes a metal additive to render it conductive.

19. The method of claim 1 further comprising, before the step of applying the glass frit mixture to the first surface of the receiver element, depositing a titanium layer on the first surface of the receiver element.

20. The method of claim 1 further comprising, before the step of applying the glass frit mixture to the first surface of the donor body, depositing a titanium layer on or above the first surface of the donor body.

21. The method of clam 20 wherein a dielectric layer is disposed between the titanium layer and the first surface of the donor body, wherein the titanium is in electrical contact with the donor body through openings in the dielectric layer.

22. The method of claim 1 wherein the donor body is monocrystalline silicon.

23. A method to fabricate a structure, the method comprising:
providing a semiconductor donor body, wherein a cleave plane has been defined within the donor body;
providing a receiver element;
applying a mixture containing glass frit to a first surface of the donor body or to a first surface of the receiver element;
heating the applied glass frit mixture to at least 325 degrees C.;
after the step of heating the applied glass frit mixture, placing the first surface of the donor body and the first surface of the receiver element in contact, the heated glass frit mixture disposed between them; and
heating the donor body and the receiver element, wherein, during this heating step, a lamina cleaves from the donor body at the cleave plane, the lamina remaining permanently adhered to the receiver element,
wherein the lamina is suitable for use in a photovoltaic cell.
